(19) United States
(12) Patent Application Publication
(10) Pub. No.: US 2009/0191338 A1
(43) Pub. Date: Jul. 30, 2009

(54) Film-Deposition Apparatus and Film-Deposition Method

(75) Inventors: Kenji Matsumoto, Yamanashi-Ken (JP); Hiroshi Sato, Yamanashi-Ken (JP); Tatsuya Ohira, Yamanashi-Ken (JP); Hideaki Machida, Yamanashi-Ken (JP); Masato Ishikawa, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(73) Assignees: TOKYO ELECTRON LIMITED, Tokyo (JP); TRI CHEMICAL LABORATORIES INC., Uenohara-shi (JP)

(21) Appl. No.: 12/226,217

(22) PCT Filed: Apr. 18, 2007
(86) PCT No.: PCT/JP2007/058409

§ 371 Date: Oct. 10, 2008

(30) Foreign Application Priority Data
Apr. 19, 2006 (JP) 2006-116020
Nov. 17, 2006 (JP) 2006-311117

(51) Int. Cl. C23C 16/06; C23C 16/54

(52) U.S. Cl. 427/255.28; 118/728; 118/722

(57) ABSTRACT

A film-deposition apparatus and a film-deposition method for forming a manganese film on a surface of an object to be processed by a CVD method are provided. The film-deposition apparatus for forming a manganese film on a surface of an object to be processed by a CVD method (Chemical Vapor Deposition method), the film-deposition apparatus comprises: a process vessel capable of being evacuated; a table on which the object to be processed can be placed, the table being disposed in the process vessel; and a source-gas supply part connected to the process vessel, the source-gas supply part being configured to supply, into the process vessel, a source gas including an organic metal material containing manganese or a metal complex material containing manganese. The film-deposition method for forming a manganese film on a surface of an object to be processed by a CVD method (Chemical Vapor Deposition method), the film-deposition method comprises the steps of: placing an object to be processed in an inside of a process vessel capable of being evacuated; and forming a manganese film on a surface of the object to be processed in the process vessel by the CVD method with the use of a source gas including an organic metal material containing manganese or a metal complex material containing manganese.

### CROSS REFERENCE TO RELATED APPLICATIONS

This application is based upon the International Application No. PCT/JP2007/058409 filed on Apr. 18, 2007, the entire contents of which are incorporated herein by reference.

### FIELD OF THE INVENTION

The present invention relates to a film-deposition apparatus and a film-deposition method for forming a manganese (Mn) film on a surface of an object to be processed such as a semiconductor wafer by a CVD method (Chemical Vapor Deposition method).

### BACKGROUND ART

When a semiconductor device is manufactured, various processes such as a film-deposition process and a pattern etching process are generally repeatedly performed to a semiconductor wafer so as to manufacture a desired device. In order to cope with a need for further integration and further miniaturization of a semiconductor device, a line width and a hole diameter of the semiconductor device has been more and more reduced. As a wiring material in a semiconductor device and a material to be embedded in a recess such as a trench and a hole of a semiconductor wafer, there has been a tendency for using copper which has a significantly small electric resistance and is inexpensive (see, JP2000-77365A). This is because it is necessary to further reduce the electric resistance of a material in accordance with the various reduced dimensions of the semiconductor device. When copper is used as the wiring material and the embedded material, tantalum metal (Ta) or a tantalum nitride film (TaN) or the like is generally used as a barrier layer, in consideration of a diffusion barrier property of copper to a lower layer.

In order to fill the recess formed in a semiconductor wafer, a thin seed film made of a copper film is firstly formed on the overall wafer surface including the whole wall surface in the recess by a plasma spattering apparatus, and then the overall wafer surface is subjected to a copper plating process, so that the inside of the recess is completely filled. Thereafter, the excessive copper thin film on the wafer surface is removed by a CMP (Chemical Mechanical Polishing) process or the like.

The filling of such a recess formed in a semiconductor wafer is concretely described with reference to FIG. 7. FIG. 7 is a view showing a series of conventional steps for filling a recess of a semiconductor wafer. An SiO₂ layer 1 as a base is formed on a surface of the semiconductor wafer W. The SiO₂ layer 1 is provided with a recess 2 that will serve as a via hole, a through-hole, or a groove (a trench or a dual damascene structure). In accordance with the miniaturization by the design rule, the recess 2 has a significantly large aspect ratio (═depth/opening width (or opening diameter)), which is as large as e.g., 3 to 4, and a width or an inner diameter is, e.g., about 120 nm.

On the surface of the semiconductor wafer W including an inner surface of the recess 2, there has been substantially uniformly formed beforehand a barrier layer 4, which is of a layered structure including, e.g., a TaN film and a Ta film, by a plasma spattering apparatus (see, FIG. 7(A)). Then, a seed film 6 of a thin copper film as a metal film is formed over all the surface including the inside surface of the recess 2 by the plasma spattering apparatus (see, FIG. 7(B)). During the formation of the seed film 6 in the plasma spattering apparatus, a bias power of a high frequency voltage is applied to the semiconductor wafer side so as to promote efficient drawing of metal ions of copper. Then, the wafer surface is subjected to a copper plating process, so that the recess 2 is filled with, e.g., a metal film 8 made of a copper film (see, FIG. 7(C)). Subsequently, the excessive metal film 8, the seed film 6, and the barrier layer 4 on the wafer surface are removed by the CMP process or the like.

Recently, with a view to further improving a reliability of the barrier layer, various developments have been made. Especially, a self-forming barrier layer using a CuMn alloy film has been regarded (see, JP2005-277390A, for example). The CuMn alloy film is deposited by spattering. After the film-deposition, the CuMn alloy film is annealed, so that the CuMn alloy film reacts with a lower SiO₂ layer as an insulation film in a self-aligning manner. Thus, an MnSiₓO_{y} (x, y: given integer) film as a barrier film is formed on a boundary part between the SiO₂ layer and the CuMn alloy film. In addition, since the CuMn alloy film itself functions as a seed film, a Cu plating layer can be directly formed above the CuMn alloy film. This is advantageous in that the number of manufacturing steps can be decreased.

### DISCLOSURE OF THE INVENTION

At the current practical level, the CuMn alloy can be formed only by the spattering method. However, there is a possibility that the spattering method cannot sufficiently deal with an extremely miniaturized pattern that is expected in the future, such as a trench/hole having a line width/hole diameter not more than 32 nm in a semiconductor wafer, which results in insufficient filling.

As a method of eliminating this problem, it can be considered that a CuMn alloy film is deposited by the CVD method (Chemical Vapor Deposition method). However, a technique for depositing the CuMn alloy film by the CVD method at a relatively lower temperature has not been conventionally established. In addition, regarding solely a manganese film which is considered to be more easily deposited than the CuMn alloy film, an art for depositing such a manganese film by the CVD method at a relatively lower temperature has not been also conventionally established.

In view of the above problems, the present invention has been made to effectively solve the same. The object of the present invention is to provide a film-deposition method and a film-deposition apparatus, capable of forming a manganese film on a surface of an object to be processed, such as a semiconductor wafer, by the CVD method at a relatively lower temperature.

A film-deposition apparatus of the present invention is a film-deposition apparatus for forming a manganese film on a surface of an object to be processed by a CVD method (Chemical Vapor Deposition method), the film-deposition apparatus comprising: a process vessel capable of being evacuated; a table on which the object to be processed can be placed, the table being disposed in the process vessel; and a source-gas supply part connected to the process vessel, the source-gas supply part being configured to supply, into the process vessel, a source gas including an organic metal material containing manganese or a metal complex material containing manganese.

According to such a film-deposition apparatus, since the source gas including an organic metal material containing manganese or the source gas including a metal complex material containing manganese is used, a manganese film can be formed at a relatively lower temperature.

In the film-deposition apparatus, it is preferable that the film-deposition apparatus further comprises a reduction-gas supply part connected to the process vessel, the reduction-gas supply part being configured to supply a reduction gas into the process vessel.

According to such a film-deposition apparatus, since the reduction gas is used as an assist gas during the film deposition, a manganese film can be formed at a still lower temperature.

In addition, in this case, it is preferable that the source gas and the reduction gas are mixed with each other in the process vessel.

In addition, it is preferable that the source-gas supply part includes: a material tank for storing a material in a liquid state; and a bubbling mechanism configured to bubble and vaporize the liquid-state material by a carrier gas so as to generate the source gas.

Alternatively, it is preferable that the source-gas supply part includes: a material tank for storing a material in a liquid state; a pressure-feed mechanism configured to pressure-feed the liquid-state material by a pressurized gas; a flow-rate controller configured to control a flow rate of the liquid-state material that is pressure-fed by the pressure-feed mechanism; and a vaporizer configured to vaporize the liquid-state material that has been supplied from the flow-rate controller so as to generate the source gas.

In this case, it is possible that the material in the material tank has been liquefied by heating the material.

Alternatively, it is preferable that the material in the material tank has been liquefied by dissolving the material in an organic solvent.

With the use of a material solution that is obtained by dissolving the material in an organic solvent, a supply amount of the material solution in a liquid state can be precisely controlled. Thus, reproducibility of the film-deposition can be improved.

In addition, there is no need for heating the material in the material tank so as to make the Material into a solution, it is possible to prevent, in the material tank, thermal decomposition of the material itself and/or deterioration thereof by heat.

In addition, it is preferable that the film-deposition apparatus further comprises a heating unit configured to heat the object to be processed, so as to perform a thermal CVD method as the CVD method.

The film-deposition method of the present invention is a film-deposition method for forming a manganese film on a surface of an object to be processed by a CVD method (Chemical Vapor Deposition method), the film-deposition method comprising the steps of: placing an object to be processed in an inside of a process vessel capable of being evacuated; and forming a manganese film on a surface of the object to be processed in the process vessel by the CVD method with the use of a source gas including an organic metal material containing manganese or a metal complex material containing manganese.

According to such a film-deposition method, since the source gas including an organic metal material containing manganese or the source gas including a metal complex material containing manganese is used, a manganese film can be formed at a relatively lower temperature.

In the film-deposition method of the present invention, it is preferable that, at the step of forming a manganese film on the surface of the object to be processed by the CVD method, a reduction gas is used together with the source gas.

According to such a film-deposition method, since the reduction gas is used as an assist gas during the film deposition, a manganese film can be formed at a still lower temperature.

In addition, in this case, it is preferable that the source gas and the reduction gas are mixed with each other in the process vessel.

In addition, in the film-deposition method of the present invention, it is preferable that the reduction gas is formed of an H₂ gas.

In addition, it is preferable that the film-deposition method further comprises the step of bubbling and vaporizing a material in a liquid state so as to generate the source gas.

Alternatively, it is preferable that the film-deposition method further comprises the step of pressure-feeding a material in a liquid state by a pressurized gas while controlling a flow rate of the liquid-state material, and vaporizing the liquid-state material so as to generate the source gas.

In this case, it is possible that the material has been liquefied by heating the material.

Alternatively, it is preferable that the material has been liquefied by dissolving the material in an organic solvent.

In this case, it is preferable that the organic solvent is formed of a hydro-carbonaceous solvent or a THF (tetra hydro furan) solvent.

In addition, it is further preferable that the hydro-carbonaceous solvent contains one or more materials selected from the group consisting of pentane, cyclopentane, hexane, cyclohexane, heptane, cycloheptane, octane, and toluene.

In the film-deposition method of the present invention, it is preferable that the organic metal material is one or more materials selected from the group consisting of Mn(C₅H₅)₂, Mn(CH₃C₅H₄)₂, Mn(C₂H₅C₅H₄)₂, Mn(C₃H₇C₅H₄)₂, (CH₃C₅H₄)Mn(CO)₃, Mn(C₄H₉C₅H₄)₂, CH₃Mn(CO)₅, Mn(C₁₁H₁₉O₂)₂, Mn(C₁₁H₁₉O₂)₃, Mn(C₇H₁₁C₂H₅C₅H₄), Mn(C₅H₇O₂)₂, and Mn(C₅H₇O₂)₃.

In addition, it is preferable that the CVD method is a thermal CVD method. In this case, it is preferable that a temperature of the object to be processed is 75° C. or more when the object to be processed is subjected to a process by the thermal CVD method.

Alternatively, the CVD method may be a plasma CVD method.

### BRIEF DESCRIPTION OF THE DRAWINGS

FIG. 1 is a structural view showing a first embodiment of a film-deposition apparatus according to the present invention.

FIG. 2 is a view showing evaluation results of Examples 1 to 6 of a method of depositing a manganese film.

FIG. 3 is a view showing evaluation results of Examples 7 to 19 of the method of depositing a manganese film.

FIG. 4 is a graph showing concentrations of C and Mn in the film of Example 9.

FIG. 5 is a graph showing concentrations of C and Mn in the film of Example 16.

FIG. 6 is a structural view showing a second embodiment of the film-deposition apparatus according to the present invention.

FIG. 7 is a view showing a series of conventional steps for filling a recess in a semiconductor wafer.

### DETAILED DESCRIPTION OF THE PRESENT INVENTION

Preferred embodiments of the film-deposition apparatus and the film-deposition method according to the present invention will be described in detail below with reference to the accompanying drawings.

### FIRST EMBODIMENT OF FILM-DEPOSITION APPARATUS

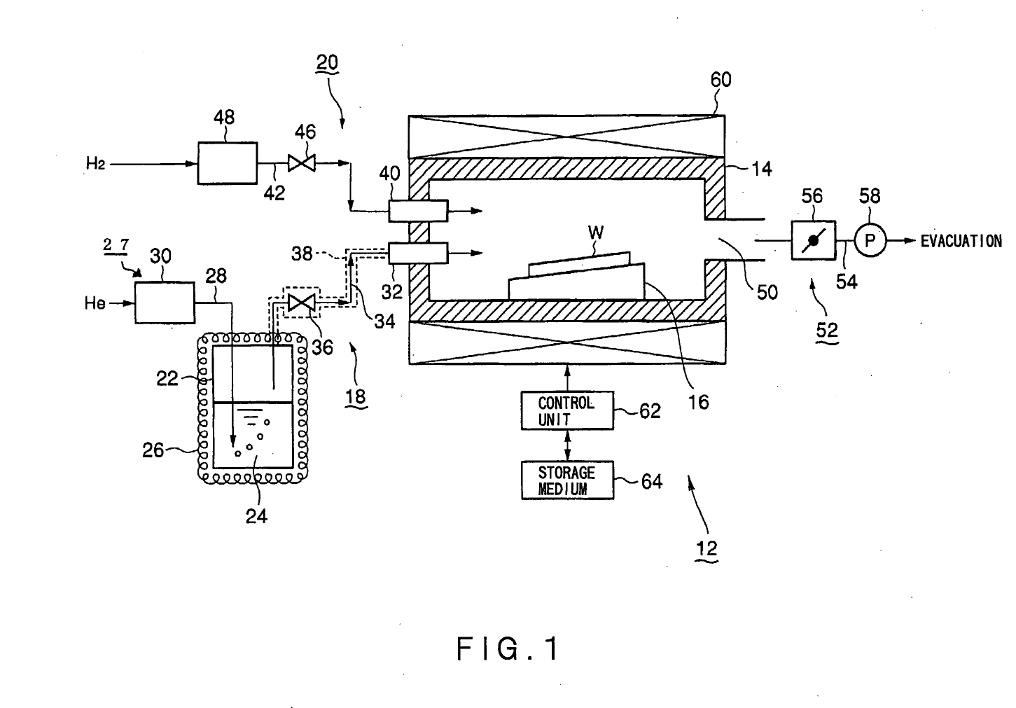

FIG. 1 is a structural view showing a first embodiment of a film-deposition apparatus according to the present invention.

As shown in FIG. 1, a film-deposition apparatus 12 in the first embodiment includes a cylindrical process vessel 14 that is laterally installed, for example. The process vessel 14 is formed of a material having a high heat resistance and a high corrosion resistance, such as quartz. Disposed in the process vessel 14 is a table 16 formed of a heat-resistive and corrosion-resistive material such as quartz or ceramic. An object to be processed, such as a semiconductor wafer W, can be placed on an upper surface of the table 16. The surface of the table 16 is slightly inclined toward an upstream side of a gas flow, so that a wafer surface and the gas flow can be effectively brought into contact with each other.

Arranged on one side of the process vessel 14 are a source-gas supply part 18 that supplies, into the process vessel 14, a source gas including an organic metal material containing manganese or a source gas including a metal complex material containing manganese, and a reduction-gas supply part 20 that supplies a reduction gas into the process vessel 14.

The source-gas supply part 18 includes a material tank 22 for storing a material 24 containing manganese. The material 24 in the material tank 22 may be solid or liquid depending on a kind thereof. There is provided a material-heating heater 26 that heats the material 24 so as to liquefy the same, if necessary. The illustration shows that the material is in a liquid state, or that the material has been liquefied from a solid state. When a material that is in a liquid state at a room temperature is used, the material-heating heater 26 may be omitted. Alternatively, it is possible to use a material that is in a solid state at a room temperature by dissolving the material with the use of an organic solvent (details of which will be described below). In this case, provision of the material-heating heater 26 is optional.

The material tank 22 is equipped with a bubbling mechanism 27. The bubbling mechanism 27 includes a piping for bubbling 28 which is inserted into the material tank 22. A flow-rate controller 30 such as a massflow controller is disposed on an intermediate position of the piping for bubbling 28. A distal end of the piping for bubbling 28 is configured to be immersed in the liquid-state material 24. By introducing a carrier gas whose flow rate is being controlled into the material 24 in the material tank 22 through the piping for bubbling 28 so as to bubble the material 24, the material 24 is vaporized and is transferred as a source gas together with the carrier gas.

A source-gas nozzle 32 made of, e.g., quartz is disposed to pass through a sidewall of the process vessel 14. A source-gas piping 34 made of, e.g., stainless is disposed such that the source-gas nozzle 32 and the material tank 22 are connected to each other. A distal end of the source-gas piping 34 is inserted into an upper space in the material tank 22, so that the source gas together with the carrier gas can be made to flow through the source-gas piping 34. An on-off valve 36 is disposed on an intermediate position of the source-gas piping 34, so that start and stop of the supply of the source gas can be controlled, if necessary. A tape heater 38 for preventing re-liquefaction of the source gas is wound around the source-gas piping 34.

As the carrier gas, an inert gas such as N₂, He, Ar, and Ne may be used. Herein, an He gas is used.

The reduction-gas supply part 20 includes a reduction-gas nozzle 40 made of, e.g. quartz, which is disposed to pass through the sidewall of the process vessel 14. Connected to the reduction-gas nozzle 40 is a reduction-gas piping 42 made of, e.g., stainless. An on-off valve 46 and a flow-rate controller 48 such as a massflow controller are disposed on intermediate positions of the reduction-gas piping 42, so that a reduction gas can be supplied while a flow rate thereof is being controlled. As the reduction gas, an H₂ gas may be used, for example. Alternatively, H₂O and a vaporized organic solvent may be used. As described below, when the reduction gas is not used, the reduction-gas supply part 20 may be omitted.

Due to the above structure, the source gas and the reduction gas, which have been supplied from the respective nozzles 32 and 40, are mixed with each other in the process vessel 14 for the first time, and thus the gases can be supplied by a post-mix method (which will be described in detail below).

In the process vessel 14, an exhaust port 50 is formed in a sidewall that is opposed to the sidewall in which the respective nozzles 32 and 40 are disposed. An exhaust system 52 is connected to the exhaust port 50. The exhaust system 52 includes an exhaust channel 54 that is connected to the exhaust port 50. A pressure-control valve 56 and a vacuum pump 58 are disposed on intermediate positions of the exhaust channel 54, so that the inside of the process vessel 14 can be evacuated and maintained at a predetermined pressure.

A heating unit 60 formed of, e.g., a resistance heater is disposed around the process vessel 14 to surround the same. The heating unit 60 can heat a wafer W in the process vessel 14 at a predetermined temperature.

A control unit 62 formed of, e.g., a microcomputer is provided to control an operation of the whole apparatus. The control unit 62 is configured to control supply amounts of the respective gases, a pressure in the process vessel 14, a temperature of a wafer W, and so on. The control unit 62 has a storage medium 64 storing a computer program for performing the above control. As the storage medium 64, a floppy disk (trademark), a flash memory, a hard disk, a CD (Compact Disc) and the like may be used, for example.

Next, a film-deposition method performed by the film-deposition apparatus 12 as structured above is described.

At first, a semiconductor wafer W is placed on the table 16 in the process vessel 14. Then, the wafer W placed on the table 16 in the process vessel 14 is heated by the heating unit 60 up to a predetermined temperature, and the thus elevated temperature is maintained. At the same time, a source gas and a reduction gas are introduced into the process vessel 14. More specifically, in the source-gas supply part 18, a material in a liquid state in the material tank 22 is bubbled by an He gas as a carrier gas whose flow rate is controlled. Thus, the material in a liquid state is vaporized. Then, the source gas is made to flow by the carrier gas through the source-gas piping 34 and is supplied into the process vessel 14 through the source-gas nozzle 32.

In the reduction-gas supply part 20, an H₂ gas as the reduction gas flows through the reduction-gas piping 42 with a flow rate of the H₂ gas being controlled, so as to be supplied into the process vessel 14 through the reduction-gas nozzle 40.

At this time, the inside of the process vessel 14 is continuously evacuated by the vacuum pump 58 of the exhaust system 52, and is maintained at a predetermined process pressure. The source gas and the H₂ gas, which have been introduced into the process vessel 14 through the gas nozzles 32 and 40, are mixed with each other in the process vessel 14, and the mixed gas flows to a downstream side while contacting a surface of the wafer W. At this time, the source gas is decomposed by a thermal CVD reaction and is reduced by the H₂ gas, so that a manganese film is deposited on the surface of the wafer W. In a case where the reduction gas is not used, the source gas is solely supplied, and the thus supplied source gas is decomposed by the thermal CVD reaction, so that a manganese film is deposited on the surface of the wafer W.

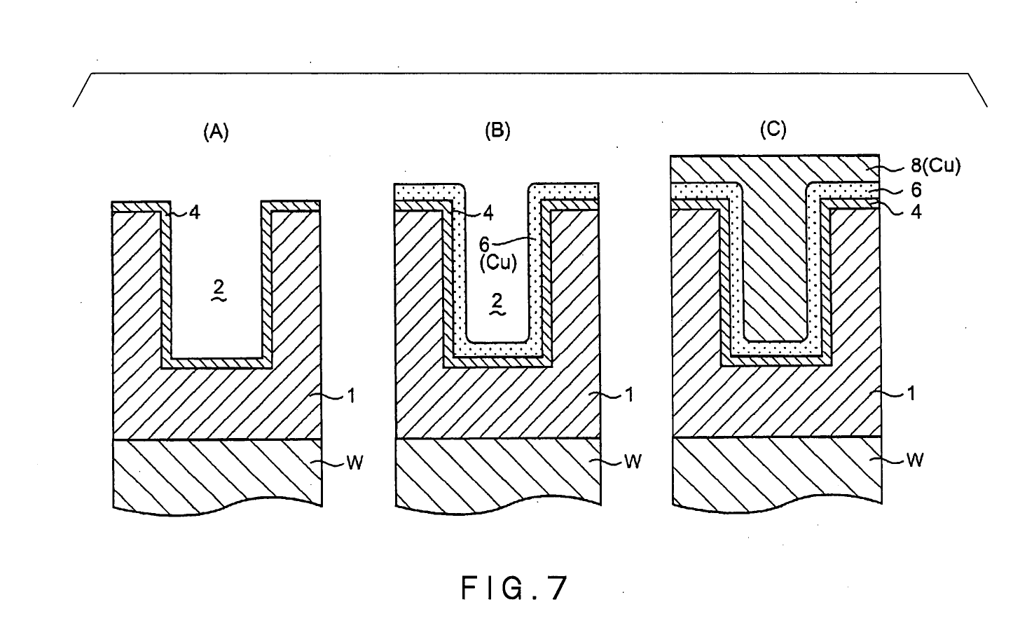

Owing to the film-deposition by the thermal CVD reaction, in a case in which the base SiO₂ layer 1 shown in FIG. 7 has a significantly minute recess having a diameter or line width as small as about 32 nm, i.e., there is a hole or a trench in the SiO₂ layer 1, a manganese film can be deposited even on an inside wall surface of the recess at a relatively low temperature.

In this case, the process pressure is within a range between 2.9 kPa and 80 kPa. The process temperature is within a range between 75° C. and 450° C., preferably between 90° C. and 450° C. When the process temperature exceeds 450° C., there is a possibility that the respective base layers (e.g., lower semiconductor device), which have been previously formed on the wafer surface, are thermally damaged.

### EXAMPLES 1 TO 6

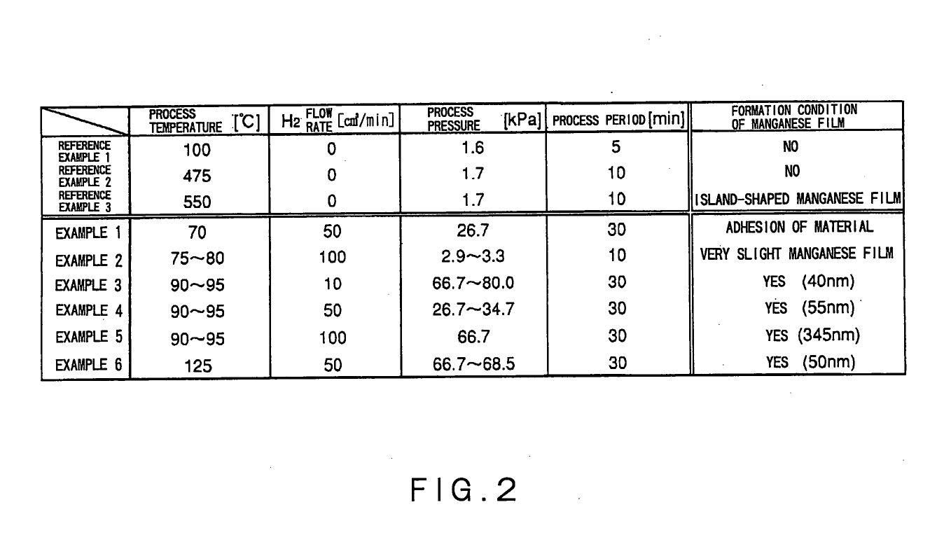

Next, a manganese film was actually deposited with the use of the above film-deposition apparatus 12 and the film-deposition results were evaluated. The evaluation results are described below with reference to FIG. 2. FIG. 2 is a view showing the evaluation results of Examples 1 to 6 of the method of depositing a manganese film.

In this case, as the material 24, (MeCp)₂Mn[═Mn (CH₃C₅H₄)₂], which was used as a precursor, was bubbled by an He gas (carrier gas) so as to be evaporated, and the thus generated source gas was supplied into the process vessel 14. The material 24 was heated at 60° C. to 70° C. The source-gas piping 34 and the on-off valve 36 were heated at 75° C. to 80° C. An H₂ gas was used as the reduction gas. The process pressure was varied within a range between 1.6 kPa and 80 kPa, and the process temperature was varied within a range between 70° C. and 550° C. As a wafer W, there was used a silicon wafer on which SiO₂ was deposited by plasma TEOS (Tetra Ethyl Ortho Silicate).

As shown in FIG. 2, in the Reference Examples 1 to 3, an H₂ gas was not supplied. In these cases, when the process temperature was not more than 475° C., there was deposited no manganese film at all (Reference Examples 1 and 2). Meanwhile, when the process temperature was 550° C., only a small island-shaped manganese film was deposited (Reference Example 3). Namely, it can be understood that, without the supply of an H₂ gas, no manganese film can be deposited at a temperature as low as 475° C. or less.

On the other hand, in the Examples 1 to 6, an H₂ gas was supplied at a flow rate within a range between 10 cm³/min and 100 cm³/min (SCCM, Standard Cubic Centimeter per Minute). In these cases, the process pressure was varied within a range between 2.9 kPa and 80 kPa. When the process temperature was 70° C., only the material adhered to the wafer surface (Example 1), and no manganese film was deposited. In each of the Examples 2 to 6 in which the process temperature was not less than 75° C., a manganese film, which was a continuous film, was deposited on the wafer surface. A thickness of each of the films was measured by using an SEM (Scanning Electron Microscope). Namely, it can be understood that, with the supply of an H₂ gas, a manganese film can be deposited at a process temperature not less than 75° C. However, when the process temperature was 75° C. to 80° C. (Example 2), a thickness of the manganese film was very thin.

On the other hand, when the process temperature was not less than 90° C. (Examples 3 to 6), a manganese film of a sufficient film-deposition amount could be formed, without being affected much by the H₂ flow rate and also without being affected much by the process pressure. From these experiment results, it could be confirmed that the process pressure is preferably set within a range between 90° C. and 450° C. As has been described above, in the examples, by heating the material 24 at 60° C. to 70° C. and heating the source-gas piping 34 and the on-off valve 36 at 75° C. to 80° C., the vaporized material was supplied into the process vessel 14.

Meanwhile, in the case where an H₂ gas is supplied as the reduction gas, the temperature at which a manganese film starts to be deposited is 75° C. Thus, if an H₂ gas is used as a carrier gas to bubble the material, there is possibility that a manganese film is deposited on the insides of the material tank 22, the source-gas piping 34, the on-off valve 36, and the source-gas nozzle 32, causing generation of particles and blocking of the piping. Thus, it can be understood that, in the film-deposition apparatus 12, the source-gas supply part 18 and the reduction-gas supply part 20 have to be independently installed, so as to employ the post-mix method in which the source gas and the reduction gas are mixed with each other in the process vessel 14 for the first time.

In addition, even when the post-mix method is employed, the Mn source gas and the reduction gas are mixed with each other near the source-gas nozzle 32 and the reduction-gas nozzle 40 disposed in the sidewall of the process vessel 14. Thus, unless the temperature is properly controlled, an undesired film may be formed on the sidewall of the process vessel 14 and a part near the nozzles, and/or particles may be generated in the gas phase. Thus, a desired set temperature near the gas nozzles 32 and 40 is studied below. A temperature for heating the Mn material 24, which is required to stably supply the (MeCp)₂Mn (precursor) gas by bubbling, is 60° C. to 70° C., as described above. With a temperature below this temperature, there is a possibility that the Mn source gas is re-liquefied.

On the other hand, since the lowest temperature at which an Mn film is deposited with the presence of H₂ as the reduction gas is 75° C. to 80° C., as described above, and a sufficient amount of Mn film can be obtained at a temperature as high as 90° C., a temperature exceeding this temperature may induce a film-deposition reaction of the Mn source gas. In consideration of the above-described temperature property, it can be understood that a temperature range, which allows neither the re-liquefaction of the (MeCp)₂Mn (precursor) gas with the presence of H₂ as the reduction gas nor the film-deposition reaction thereof, is 60° C. to 90° C., more reliably 70° C. to 80° C. Namely, when the temperature near the gas nozzles 32 and 40 is set within a range between 60° C. and 90° C., more preferably 70° C. and 80° C., formation of an undesired film on the sidewall of the process vessel 14 and a part near the gas nozzles 32 and 40 and/or generation of particles in the gas phase can be prevented. These set temperatures can be applied to a process vessel 66 and a showerhead part 72 in the below-described film-deposition apparatus in a second embodiment.

### EXAMPLES 7 TO 19

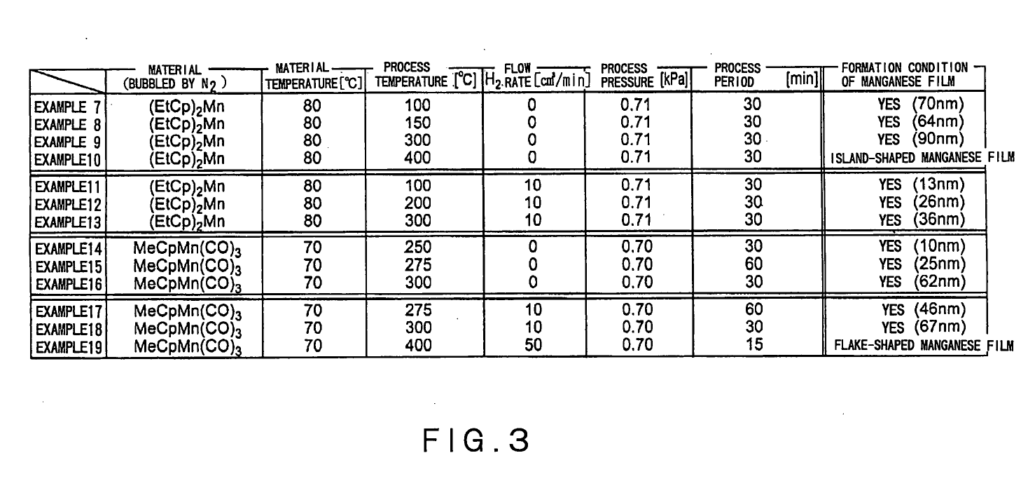

Examples 7 to 19 were conducted in which an (EtCp)₂ Mn[═Mn(C₂H₅C₅H₄)₂] gas or an MeCpMn(CO)₃[═(CH₃C₅H₄) Mn(CO)₃] gas was used as the material 24, and the results were evaluated. FIG. 3 is a view showing the evaluation results of Examples 7 to 19 of the method of depositing a manganese film.

The general flow of the film-deposition process is the same as the process described with reference to FIG. 2. Herein, a case in which an H₂ gas was supplied (Examples 11 to 13 and 17 to 19) and a case in which an H₂ gas was not supplied (Examples 7 to 10 and 14 to 16) were separately examined.

Regarding the (EtCp)₂Mn gas (Examples 7 to 13), the process temperature was within a range between 100° C. and 400° C., the process pressure was 0.71 kPa, the process period was 30 minutes, and the material was heated at 80° C. H₂ was made to flow at flow rates of 10 cm³/min (Examples 11 to 13) and 0 (Examples 7 to 10).

Regarding the MeCpMn(CO)₃ gas (Examples 14 to 19), the process temperature was within a range between 250° C. and 400° C., the process pressure was 0.7 kPa, the process period was 15 minutes to 60 minutes, and the material was heated at 70° C. H₂ was made to flow at flow rates of 10 cm³/min to 50 cm³/min (Examples 17 to 19) and 0 (Examples 14 to 16).

As shown in FIG. 3, in the Examples 7 to 9 and Examples 11 to 18 in which the film-deposition temperature was less than 400° C., manganese films could be formed. Thicknesses of these manganese films are shown in FIG. 3.

It could be confirmed that, when the above-described two materials are used, a manganese film can be formed without using the reduction gas (H₂) as long as the film-deposition temperature is less than 400° C. Especially in Example 7 in which the (EtCp)₂Mn gas was used, a manganese film could be formed at a temperature as low as 100° C. In Example 14 in which the MeCpMn(CO)₃ gas was used, a manganese film could be formed at a temperature of 250° C.

Similarly to Examples 1 to 6, desired set temperatures of the members are studied below. When (EtCp)₂Mn or MeCpMn(CO)₃ is used, since H₂ is not necessarily required, which is different from Examples 1 to 6 in which (MeCp)₂Mn is used, set temperatures of the parts in which Mn is vaporized, i.e., the parts including the source-gas piping 34 and the on-off valve 36 are examined.

A temperature for heating the Mn material 24, which is required to stably supply the (EtCp)₂Mn (precursor) gas by bubbling, is 60° C. to 90° C. Thus, with a temperature below this temperature, there is a possibility that the Mn source gas is re-liquefied. On the other hand, since the lowest temperature at which an Mn film is deposited is 100° C., as described above, a temperature over this temperature may induce a film-deposition reaction of the Mn source gas. In consideration of the above-described temperature property, it can be understood that a temperature range, which allows neither the re-liquefaction of the (EtCp)₂Mn (precursor) gas nor the film-deposition reaction thereof, is 60° C. to 100° C., more reliably about 90° C. Namely, when the temperature near the source-gas piping, the on-off valve, and the gas nozzle is set within a range between 60° C. and 100° C., more preferably about 90° C., formation of an undesired film on the sidewall of the process vessel and a part near the source-gas piping, the on-off valve, and the gas nozzle and/or generation of particles in the gas phase can be prevented. These set temperatures can be applied to the process vessel 66 and the showerhead part 72 in the below-described film-deposition apparatus in a second embodiment.

A temperature for heating the Mn material 24, which is required to stably supply the MeCpMn(CO)₃ (precursor) gas by bubbling, is 40° C. to 90° C. Thus, with a temperature below this temperature, there is a possibility that the Mn source gas is re-liquefied. On the other hand, since the lowest temperature at which an Mn film is deposited is 250° C., as described above, a temperature over this temperature may induce a film-deposition reaction of the Mn source gas. In consideration of the above-described temperature property, it can be understood that a temperature range, which allows neither the re-liquefaction of the MeCpMn(CO)₃ (precursor) gas nor the film-deposition reaction thereof, is 40° C. to 250° C., more reliably 90° C. to 240° C. Namely, when the temperature near the source-gas piping, the on-off valve, and the gas nozzle is set within a range between 40° C. and 250° C., more preferably 90° C. 240° C., formation of an undesired film on the sidewall of the process vessel and a part near the source-gas piping, the on-off valve, and the gas nozzle and/or generation of particles in the gas phase can be prevented. These set temperatures can be applied to the process vessel 66 and the showerhead part 72 in the below-described film-deposition apparatus in a second embodiment.

In Example 9 in which the (EtCp)₂Mn gas was used and in Example 16 in which the MeCpMn(CO)₃ gas was used, concentrations of C (carbon) and Mn (manganese) in the film were measured by an SIMS (Secondary Ion Mass Spectrometry). The measurement results are described below.

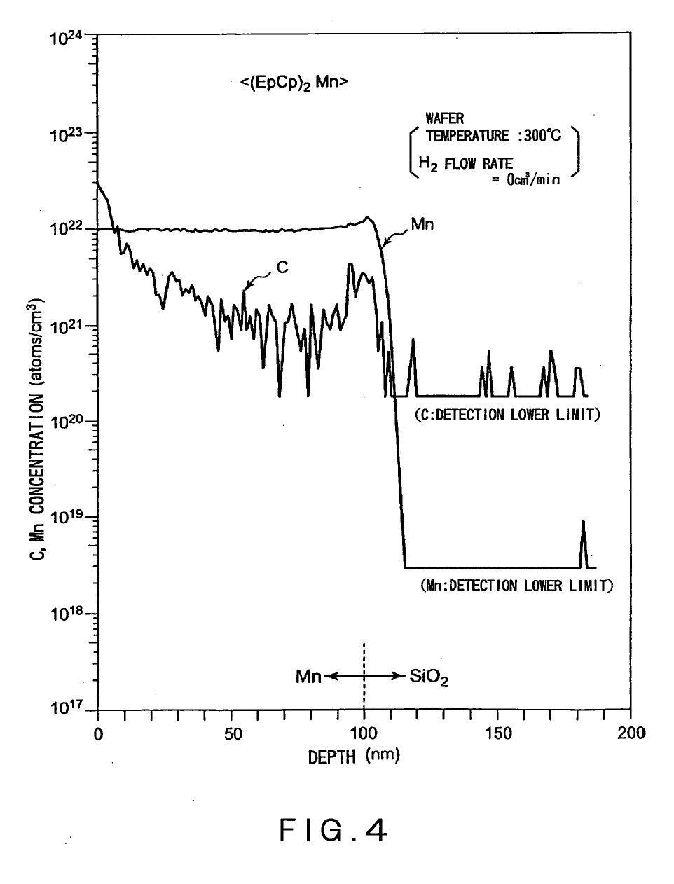

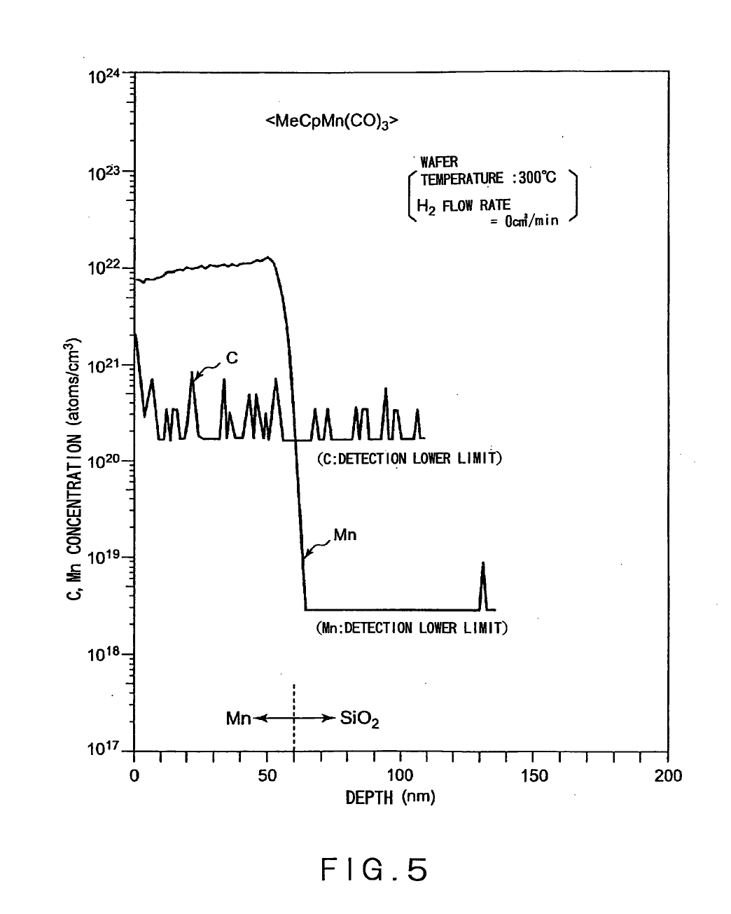

FIG. 4 is a graph showing concentrations of C and Mn in the film of Example 9, and FIG. 5 is a graph showing concentrations of C and Mn in the film of Example 16. As has been described above, in both Examples 9 and 16, a supply amount of an H₂ gas was 0, the process temperature was 300° C., and the process pressure was about 0.7 kPa.

From the graph shown in FIG. 4 in which the (EtCp)₂Mn gas was used, it could be confirmed that an Mn film was formed on the SiO₂ film with a depth (thickness) of about 100 nm and an Mn concentration of about 10²² atoms/cm³. With respect to the C concentration, it could be confirmed that C was contained in the Mn film at 10²¹ atoms/cm³.

From the graph shown in FIG. 5 in which the MeCpMn(CO)₃ gas was used, it could be confirmed that an Mn film was formed on the SiO₂ film with a depth (thickness) of about 60 nm and an Mn concentration of about 10²² atoms/cm³. With respect to the C concentration, since only about 3×10²⁰ atoms/cm³ of C, which is near a lower detection limit of C in the Mn film, was contained in the Mn film, it could be confirmed that the C concentration in the Mn film was far smaller than the case shown in the graph of FIG. 4.

When the data of FIGS. 4 and 5 were measured by the SIMS, since priority was given to a measurement precision of Mn, the C concentration was measured with a lower detection sensibility. In addition, since the C concentration in the Mn film could not be calibrated, the C concentration was not so exact in terms of an absolute value. However, it was possible to compare the C concentrations as relative values between the samples. That is to say, since the concentration of C contained in the Mn film formed by using the MeCpMn(CO)₃ gas shown in FIG. 5 is about ten times smaller than the concentration of C contained in the Mn film formed by using (EtCp)₂Mn gas shown in FIG. 4, there can be expected an improved film quality such as improvement in contact strength of the Mn film and reduction in electric resistance.

In each of the graphs shown in FIGS. 4 and 5, since the Mn profile at the Mn/SiO₂ interface is precipitous and there is no tail of the Mn profile on the side of the SiO₂, it could be confirmed that no Mn was interfused toward the SiO₂.

In addition to the film-deposition conditions shown in FIG. 3, the inventors sought process conditions for depositing an Mn film. It was found that preferable film-deposition conditions when the (EtCp)₂Mn gas was used were: the process temperature of 90° C. to 400° C.; the H₂ flow rate of not more than 100 cm³/min; the process pressure of 0.133 kPa to 1.33 kPa; the process period of 15 minutes to 60 minutes; and the material-heating temperature of 60° C. to 90° C. Meanwhile, preferable film-deposition conditions when the MeCpMn(CO)₃ gas was used were: the process temperature of 250° C. to 400° C.; the H₂ flow rate of not more than 100 cm³/min; the process pressure of 0.133 kPa to 1.33 kPa; the process period of 15 minutes to 60 minutes; and the material-heating temperature of 40° C. to 90° C.

### SECOND EMBODIMENT OF FILM-DEPOSITION APPARATUS

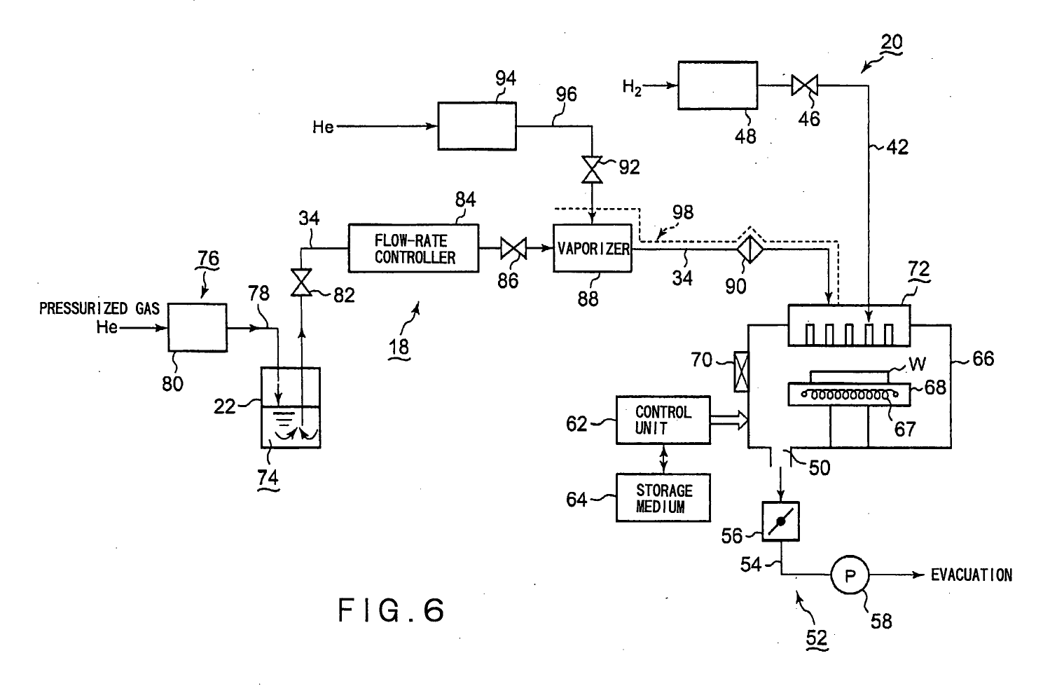

Next, a second embodiment of the film-deposition apparatus of the present invention is described. FIG. 6 is a structural view showing a second embodiment of the film-deposition apparatus according to the present invention. Herein, the same structural members as those shown in FIG. 1 are indicated by the same reference numbers, and the detailed description thereof is omitted.

As shown in FIG. 6, a film-deposition apparatus in the second embodiment includes a cylindrical process vessel 66 made of, e.g., an aluminum alloy. In the process vessel 66, a circular table 68, which has a heating unit 67 made of a resistance heater, is disposed to project from a bottom of the vessel. A semiconductor wafer W can be placed on the table 68.

An exhaust port 50 is formed in the bottom of the process vessel 66. An exhaust system 52 is constituted by connecting, to the exhaust port 50, an exhaust channel 54 in which a pressure-control valve 56 and a vacuum pump 58 are disposed. Disposed in a sidewall of the process vessel 66 is a gate valve 70 that is opened and closed when a wafer W is loaded into and unloaded from the process vessel 66.

Arranged on a ceiling part of the process vessel 66 is, for example, a showerhead part 72 as means for introducing a gas. The showerhead part 72 is provided with a plurality of divided gas diffusion chambers (not shown), and plural kinds of gases can be separately introduced into the process vessel 66 so as to realize a so-called post-mix method. A reduction-gas supply part 20 is connected to one of the gas diffusion chambers, and an H₂ gas can be supplied from the reduction-gas supply part 20. The reduction-gas supply part 20 is composed of a reduction-gas piping 42, an on-off valve 46, and a flow-rate controller 48 which are disposed in the reduction-gas piping 42.

A source-gas supply part 18 is connected to another gas diffusion chamber. To be specific, the source-gas supply part 18 includes a source-gas piping 34 through which a source gas flows, and a proximal end of the source-gas piping 34 is connected to a material tank 22. Stored in the material tank 22 is a material solution 74 which has been liquefied by dissolving a material in an organic solvent. In this case, the material is dissolved in the organic solvent such that the material solution is maintained in a liquid state at a room temperature, which is different from the film-deposition apparatus shown in FIG. 1. If necessary, a heater for heating a material may be provided. Herein, for example, (MeCp)₂Mn [═Mn(CH₃C₅H₄)₂] is used as the material, while hexane is used as the organic solvent. An end of the source-gas piping 34 is immersed in the material solution 74.

The material tank 22 is equipped with a pressure-feed mechanism 76 for pressure-feeding the material solution 74 by a pressurized gas. The pressure-feed mechanism 76 has a pressure-feed gas pipe 78 whose distal end is inserted to an upper space in the material tank 22. The pressure-feed gas pipe 78 includes a pressure regulator 80. The pressurized gas can be supplied from a gas source, not shown, by the pressure regulator 80 into the material tank 22, so that the material solution 74 can be pressure-fed into the source-gas piping 34. Although He is used as the pressurized gas, for example, a rare gas such as He, Ar, and Ne may be used, or an inert gas such as N₂ may also be used.

The source-gas piping 34 is provided with a first on-off valve 82, a flow-rate controller 84, a second on-off valve 86, a vaporizer 88, and a filter 90, in this order from the upstream side to the downstream side. The material solution 74 can be made to flow through the source-gas piping 34, with a flow rate of the material solution 74 being precisely controlled by the operation of the flow-rate controller 84. Connected to the vaporizer 88 is a vaporized-gas pipe 96. An on-off valve 92 and a flow-rate controller 94 are disposed on intermediate positions of the vaporized-gas pipe 96. Thus, the material solution 74 which has flown into the vaporizer 88 can be vaporized and made to flow toward the process vessel 66. Herein, although He, for example, is used as the vaporized gas, for example, a rare gas such as He, Ar, and Ne may be used, or an inert gas such as N₂ may also be used. A tape heater 98 is wound around a part of the source-gas piping 34 which is nearer to the downstream side than the vaporizer 88. Thus, by heating the source-gas piping 34 to a predetermined temperature, the source gas can be prevented from being re-liquefied.

A film-deposition process of the film-deposition apparatus in the second embodiment as structured above is basically the same as that of the first embodiment which has been described with reference to FIG. 1. However, in the second embodiment, the material in a solid state is dissolved in the organic solvent to obtain the material solution 74, the material solution 74 in a liquid state is pressure-fed by the pressure-feed mechanism 76, and the material solution 74 is vaporized by the vaporizer 88 while a flow rate of the material solution 74 is being controlled by the flow-rate controller 84. Thus, controllability of a supply amount of the material solution 74 can be improved, which in turn can improve reproducibility of the film-deposition.

Further, there is no need for heating the material tank 22, it is possible to prevent, in the material tank 22, thermal decomposition of the material solution 74 and/or deterioration thereof by heat. Furthermore, since a material of a lower vapor pressure can be vaporized and supplied, alternatives to be used as the Mn material can be increased.

In the film-deposition apparatus shown in FIG. 6, it is possible to use, as the source-gas supply part 18, a source-gas supply part using the bubbling mechanism 27 shown in FIG. 1. Reversely, in the film-deposition apparatus as shown in FIG. 1, it is possible to use, as the source-gas supply part 18, a source-gas supply part using the pressure-feed mechanism 76 as shown in FIG. 6.

In the above embodiment, although hexane is taken as an example of the organic solvent, it is naturally not limited to this aspect. Specifically, as the organic solvent, a hydro-carbonaceous solvent or a THF (tetra hydro furan) solvent may be used, for example. As the hydro-carbonaceous solvent, it is possible to use one or more materials selected from the group consisting of pentane, cyclopentane, hexane, cyclohexane, heptane, cycloheptane, octane, and toluene. In particular, (MeCp)₂Mn can be sufficiently dissolved in the THF solution, hexane, and toluene, at about 0.3 mol/liter at maximum. Samples of these combinations at a concentration of 0.1 mol/liter to 0.3 mol/liter were actually made and dissolution experiments were conducted. It could be confirmed that the (MeCp)₂Mn was soluble in all of the samples without any deposition of solids. In addition, after the samples were left for one month, it could be confirmed that there was no deposition of solids.

In the second embodiment, when a material which is in a liquid state at a room temperature is used, it is not necessary to dissolve the material in an organic solvent. Further, when the (EtCp)₂Mn gas or the MeCpMn(CO)₃ gas is used, the reduction-gas supply part 20 may be omitted, as has been described in the first embodiment.

The materials used in the above respective embodiments are not limited to the above-described ones, and an organic metal material containing manganese may be used as the material. As the organic metal material, there may be used one or more materials selected from the group consisting of Cp₂Mn[═Mn(C₅H₅)₂], (MeCp)₂Mn[═Mn(CH₃C₅H₄)₂], (EtCp)₂Mn [═Mn(C₂H₅C₅H₄)₂], (i-PrCp)₂Mn[═Mn(C₃H₇C₅H₄)₂], MeCpMn(CO)₃ [═(CH₃C₅H₄)Mn(CO)₃], (t-BuCp)₂Mn[═Mn(C₄H₉C₅H₄)₂], CH₃Mn (CO)₅, Mn(DPM)₂ [═Mn(C₁₁H₁₉O₂)₂], Mn(DPM)₃[═Mn(C₁₁H₁₉O₂)₃], (EtCp)Mn(DMPD)[═Mn(C₇H₁₁C₂H₅C₅H₄)], Mn(acac)₂[═Mn(C₅H₇O₂)₂], and Mn(acac)₃[═Mn(C₅H₇O₂)₃].

Further, the material is not limited to the organic metal material containing manganese (cyclic hydro-carbonaceous precursor), and a metal complex material containing manganese may be used as the material.

Furthermore, although the film-deposition apparatus performing the thermal CVD method has been described above, the film-deposition apparatus is not limited thereto. By providing on the process vessel a plasma generation unit for generating a plasma by using a high-frequency or a microwave, a manganese film may be deposited by a plasma CVD method.

In addition, a semiconductor wafer is taken as an example of an object to be processed. However, not limited thereto, the present invention may be applied to a glass substrate, an LCD substrate, a ceramic substrate, and so on. Moreover, not limited to the field of a semiconductor device, the film-deposition apparatus and the film-deposition method of the present invention may be applied to the fields of a magnetic material, a magnetic multi-layered film, a magnetic recording material, an electrode such as an electric condenser, and an optical thin film. Further, the film-deposition method of the present invention may be used as a doping method to a ferroelectric substance and an light-emitting device.

1. A film-deposition apparatus for forming a manganese film on a surface of an object to be processed by a CVD method (Chemical Vapor Deposition method), the film-deposition apparatus comprising:
a process vessel capable of being evacuated;
a table on which the object to be processed can be placed, the table being disposed in the process vessel; and
a source-gas supply part connected to the process vessel, the source-gas supply part being configured to supply, into the process vessel, a source gas including an organic metal material containing manganese or a metal complex material containing manganese.

2. The film-deposition apparatus according to claim 1, further comprising a reduction-gas supply part connected to the process vessel, the reduction-gas supply part being configured to supply a reduction gas into the process vessel.

3. The film-deposition apparatus according to claim 2, wherein
the source gas and the reduction gas are mixed with each other in the process vessel.

4. The film-deposition apparatus according to claim 1, wherein
the source-gas supply part includes:
a material tank for storing a material in a liquid state; and
a bubbling mechanism configured to bubble and vaporize the liquid-state material by a carrier gas so as to generate the source gas.

5. The film-deposition apparatus according to claim 1, wherein
the source-gas supply part includes:
a material tank for storing a material in a liquid state;
a pressure-feed mechanism configured to pressure-feed the liquid-state material by a pressurized gas;
a flow-rate controller configured to control a flow rate of the liquid-state material that is pressure-fed by the pressure-feed mechanism; and
a vaporizer configured to vaporize the liquid-state material that has been supplied from the flow-rate controller so as to generate the source gas.

6. The film-deposition apparatus according to claim 4, wherein
the material in the material tank has been liquefied by heating the material.

7. The film-deposition apparatus according to claim 5, wherein
the material in the material tank has been liquefied by dissolving the material in an organic solvent.

8. The film-deposition apparatus according to claim 1, further comprising a heating unit configured to heat the object to be processed, so as to perform a thermal CVD method as the CVD method.

9. A film-deposition method for forming a manganese film on a surface of an object to be processed by a CVD method (Chemical Vapor Deposition method), the film-deposition method comprising the steps of:
placing an object to be processed in an inside of a process vessel capable of being evacuated; and
forming a manganese film on a surface of the object to be processed in the process vessel by the CVD method with the use of a source gas including an organic metal material containing manganese or a metal complex material containing manganese.

10. The film-deposition method according to claim 9, wherein
at the step of forming a manganese film on the surface of the object to be processed by the CVD method, a reduction gas is used together with the source gas.

11. The film-deposition method according to claim 10, wherein
the source gas and the reduction gas are mixed with each other in the process vessel.

12. The film-deposition method according to claim 10, wherein
the reduction gas is formed of an H₂ gas.

13. The film-deposition method according to claim 9, further comprising the step of bubbling and vaporizing a material in a liquid state so as to generate the source gas.

14. The film-deposition method according to claim 9, further comprising the step of pressure-feeding a material in a liquid state by a pressurized gas while controlling a flow rate of the liquid-state material, and vaporizing the liquid-state material so as to generate the source gas.

15. The film-deposition method according to claim 13, wherein
the material has been liquefied by heating the material.

16. The film-deposition method according to claim 14, wherein
the material has been liquefied by dissolving the material in an organic solvent.

17. The film-deposition method according to claim 16, wherein
the organic solvent is formed of a hydro-carbonaceous solvent or a THF (tetra hydro furan) solvent.

18. The film-deposition method according to claim 17, wherein
the hydro-carbonaceous solvent contains one or more materials selected from the group consisting of pentane, cyclopentane, hexane, cyclohexane, heptane, cycloheptane, octane, and toluene.

19. The film-deposition method according to claim 9, wherein
the organic metal material is one or more materials selected from the group consisting of Mn(C₅H₅)₂, Mn(CH₃C₅H₄)₂, Mn(C₂H₅C₅H₄)₂, Mn(C₃H₇C₅H₄)₂, (CH₃C₅H₄)Mn(CO)₃, Mn(C₄H₉C₅H₄)₂, CH₃Mn(CO)₅, Mn(C₁₁H₁₉O₂)₂, Mn(C₁₁H₁₉O₂)₃, Mn(C₇H₁₁C₂H₅C₅H₄), Mn(C₅H₇O₂)₂, and Mn(C₅H₇O₂)₃.

20. The film-deposition method according to claim 9, wherein
the CVD method is a thermal CVD method.

21. The film-deposition method according to claim 20, wherein
a temperature of the object to be processed is 75° C. or more when the object to be processed is subjected to a process by the thermal CVD method.

22. The film-deposition method according to claim 9, wherein the CVD method is a plasma CVD method.
